(19) United States
(12) Patent Application Publication
(10) Pub. No.: US 2016/0118561 A1
(43) Pub. Date: Apr. 28, 2016

(54) CIRCUIT STRUCTURE OF A FLIP-CHIP LIGHT EMITTING DIODE

(71) Applicant: Genesis Photonics Inc., Tainan City (TW)

(72) Inventors: Cheng-Wei Hung, Tainan City (TW); Meng-Ting Tsai, Tainan City (TW); Yu-Feng Lin, Tainan City (TW)

(21) Appl. No.: 14/733,957

(22) Filed: Jun. 8, 2015

(30) Foreign Application Priority Data
Oct. 28, 2014 (TW) 103137181

(51) Int. Cl. H01L 33/62; H01L 25/075; H01L 33/60

(52) U.S. Cl. CPC H01L 33/62; H01L 33/60; H01L 25/0753

(57) ABSTRACT

The invention relates to a circuit structure of a flip-chip light emitting diode. It is provided for assembling of the flip-chip light emitting diode. Each flip-chip light emitting diode has at least two electrodes. The circuit structure defines a light emitting surface on a surface of a substrate, and the light emitting surface is provided with a plurality of reflective and conductive surfaces. The reflective and conductive surface is used for assembling of the electrodes of the flip-chip light emitting diode. At least one flip-chip light emitting diode is connected in series, parallel or series-parallel on the light emitting surface, wherein the total area of the reflective and conductive surface accounts for 80% to 99% of the area of the light emitting surface. Accordingly, the circuit structure of the flip-chip light emitting diode can efficiently improve the luminous efficiency of flip-chip light emitting diode device by adding a proportion of the area of the reflective conduction surfaces on the substrate of the flip-chip light emitting diode.

### CROSS-REFERENCE TO RELATED APPLICATION

This application claims the priority benefit of Taiwan application serial no. 103137181, filed on Oct. 28, 2014. The entirety of the above-mentioned patent application is hereby incorporated by reference herein and made a part of this specification.

### BACKGROUND OF THE INVENTION

1. Field of the Invention

The invention relates to a circuit structure of a flip-chip light emitting diode, particularly relates to a circuit layout of a light emitting diode with an increased area of reflective and conductive surfaces on a substrate, where a luminous efficiency of a flip-chip light emitting diode device is effectively increased by increasing a proportion of the area of the reflective and conductive surfaces on the substrate of the flip-chip light emitting diode.

2. Description of Related Art

Compared with the conventional incandescent light source, the light emitting diode (LED) has the advantages of low power consumption, small size, low driving voltage, mercury free, thermal radiation free, quick response, and long lifetime, etc. Accordingly, LED is the most ideal light source in the energy-saving luminaires of the next generation. Currently, LED has been broadly used in luminaires such as indicators of home appliances, backlight sources of liquid crystal displays, displays for text and figures, and high-mounted stop lamp, etc. The principle of light emission of LED is described as follows. A voltage is applied to a diode to drive the combination of the electrons and holes in the diode. Then, the energy generated through such combination is released in the form of light, thereby allowing the light emitting diode to emit light.

The flip-chip light emitting diode is developed to solve the high thermal impedance and the difficulty in heat dissipation due to the conventional use of a silver paste to adhere the light emitting diode chip substrate and the packaging base material. By directly bonding the electrode of the chip on the packaging base material, the thermal impedance of the flip-chip light emitting diode can be effectively reduced, and the luminous efficiency thereof can be improved as well. However, even the improved flip-chip light emitting diode still has a lower luminous efficiency due to the undesirable light reflection characteristics of the packaging base material. Taiwan Patent No. 1404189 has disclosed “multi-chips light emitting diode and a method for fabricating the same”, and the multi-chips light emitting diode includes a lead frame including a carrier part. A plurality of chips are disposed on the carrier part, and the plurality of chips at least include a first chip and a second chip. A first scattering layer conformally covers the first chip with only electrodes of the first chip exposed. In addition, the first scattering layer consists of a first scattering material without including any polymer material. A second scattering layer conformally covers the second chip with only electrodes of the second chip exposed. Moreover, the second scattering layer consists of a second scattering material without including any polymer material. Taiwan Patent No. 1404189 uses the same or different scattering materials and thicknesses of the scattering layers to control the light emitting angles of the respective chips, and the scattering layers do not contain any material other than the scattering materials, so the accuracy of angle is improved. Thus, the light emitting angles of different chips after packaging are respectively effectively controlled, and the stability thereof is improved as well. However, in the light emitting diode device, except for areas around the light emitting diode chips that emit light, which are brighter due to the light emitted by the light emitting diode chips, the remaining areas have a less preferable light reflecting effect as these area are formed of insulating materials. Thus, the overall luminous efficiency of the light emitting diode device is unable to be improved effectively.

### SUMMARY OF THE INVENTION

A circuit structure of a flip-chip light emitting diode according to the invention is capable of providing a preferable light emitting efficiency.

The invention is set to provide a circuit structure of a flip-chip light emitting diode. In particular, a circuit layout of a light emitting diode with an increased area of reflective and conductive surfaces on a substrate is provided. According to the invention, a luminous efficiency of the flip-chip light emitting diode device is effectively increased by increasing a proportion of the area of the reflective and conductive surfaces on the substrate of the flip-chip light emitting diode.

Accordingly, a circuit structure of a flip-chip light emitting diode is provided, and the lip-chip light emitting diode is configured for assembling of at least one flip-chip light emitting diode. Each of the flip-chip light emitting diode has at least two electrodes. The circuit structure comprises a substrate having a light emitting surface on a surface thereof, and a plurality of reflective and conductive surfaces disposed on the light emitting surface. In addition, the reflective and conductive surfaces are configured for assembling of the electrodes of the flip-chip light emitting diode, such that the at least one flip-chip light emitting diode is connected in series, in parallel, or in series-parallel on the light emitting surface. Moreover, a total area of the reflective and conductive surfaces accounts for 80% to 99% of an area of the light emitting surface.

According to an embodiment of the invention, in the flip-chip light emitting diode, a minimum gap between two adjacent reflective and conductive surfaces is in a range from 75 micrometers to 250 micrometers.

According to an embodiment of the invention, in the flip-chip light emitting diode, the reflective and conductive surfaces are formed of a metallic material.

According to an embodiment of the invention, in the flip-chip light emitting diode, an insulating layer is formed on the surface of the substrate, and the reflective and conductive surfaces are disposed on the insulating layer.

According to an embodiment of the invention, in the flip-chip light emitting diode, the insulating layer is formed of a material having a high reflectivity.

According to an embodiment of the invention, in the flip-chip light emitting diode, a material of the insulating layer is one of a silicon compound and an epoxy compound.

According to an embodiment of the invention, in the flip-chip light emitting diode, the substrate is one of an aluminum substrate, a copper substrate, and other suitable metallic substrates.

According to an embodiment of the invention, in the flip-chip light emitting diode, the substrate is formed of a ceramic material.

Accordingly, in the circuit structure of the flip-chip light emitting diode according to the embodiments of the invention, the proportion of the area of the reflective and conductive surfaces on the circuit board of the flip-chip light emitting diode is increased to 80% to 99% of an area of the whole light emitting surface. Thus, light beams emitted by the flip-chip light emitting diode may be reflected by the reflective and conductive surfaces formed of a metallic material, allowing the flip-chip light emitting diode device to emit more light, so as to effectively improve the luminous efficiency of the flip-chip light emitting diode device.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective view of a circuit structure illustrating a circuit structure of a flip-chip light emitting diode according to a first preferred embodiment of the invention.

FIG. 2 is a top view of a circuit structure illustrating a circuit structure of a flip-chip light emitting diode according to the first preferred embodiment of the invention.

FIG. 3 is a cross-sectional schematic view of a device illustrating a circuit structure of a flip-chip light emitting diode according to the first preferred embodiment of the invention.

FIG. 4 is a cross-sectional schematic view of a device illustrating a circuit structure of a flip-chip light emitting diode according to a second preferred embodiment of the invention.

FIG. 5 is a top view of a circuit structure illustrating a circuit structure of a flip-chip light emitting diode according to a third preferred embodiment of the invention.

FIG. 6 is a top view of a circuit structure illustrating a circuit structure of a flip-chip light emitting diode according to a fourth preferred embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The objective and characteristics of functions of the structural design of the invention are described in detail with reference to the following embodiments illustrated in the drawings to make the disclosure better understood and comprehensive.

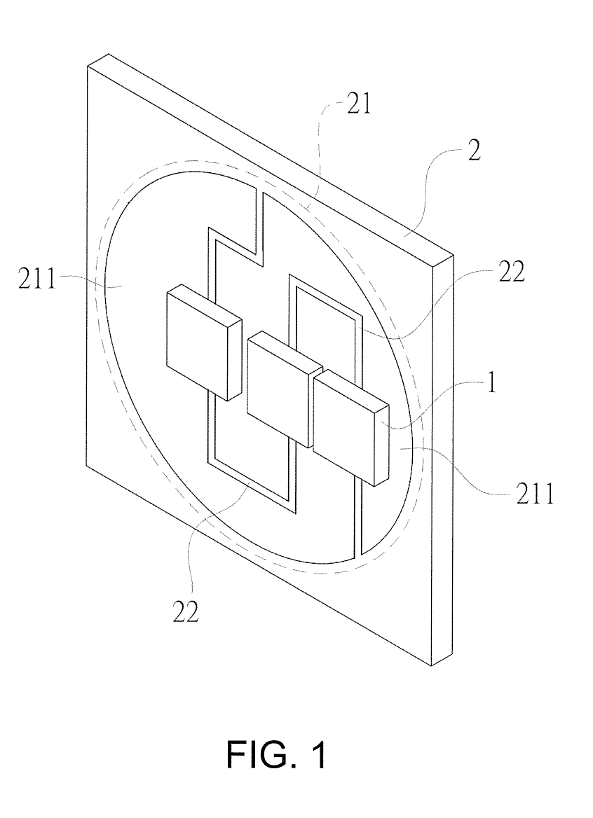

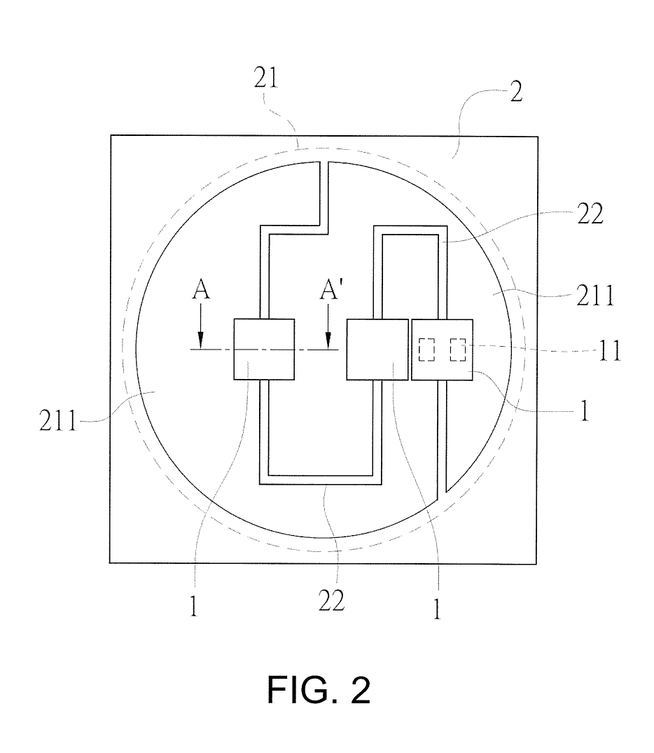

FIGS. 1 and 2 are respectively a perspective view of a circuit structure illustrating a circuit structure of a flip-chip light emitting diode according to a first preferred embodiment of the invention and a top view of a circuit structure illustrating the circuit structure of the flip-chip light emitting diode according to the first preferred embodiment of the invention. Referring to FIGS. 1 and 2, a circuit structure of a flip-chip light emitting diode of the invention is configured for assembling of at least one flip-chip light emitting diode 1. Each of the flip-chip light emitting diode has at least two electrodes 11. The circuit structure comprises a substrate 2 having a light emitting surface 21 on a surface thereof and a plurality of reflective and conductive surfaces 211 disposed on the light emitting surface 21. In addition, the reflective and conductive surface 211 is configured for assembling of the electrode 11 of the flip-chip light emitting diode 1, such that the at least one flip-chip light emitting diode 1 is connected in series, in parallel, or in series-parallel on the light emitting surface 21. In addition, a total area of the reflective and conductive surfaces accounts for 80% to 99% of an area of the light emitting surface 21. In addition, a profile of the substrate 2 may be circular, for example. However, the invention is not limited thereto. Moreover, a minimum gap 22 between two adjacent reflective and conductive surfaces 211 is in a range from 75 micrometers to 250 micrometers. Moreover, the reflective and conductive surfaces 211 are formed of a metallic material. In a preferred embodiment of the invention, the flip-chip light emitting diode 1 and the reflective and conductive surface 211 are connected to form an electrical connection through eutectic bonding. Moreover, the flip-chip light emitting diode 1 may emit light beams in the same color or in different colors. In addition, the reflective and conductive surfaces 211 formed of a metallic material are metallic bonding pads. Through the reflective and conductive surfaces 211 (i.e. bonding pads) and the electrode 11 of the flip-chip light emitting diode 1, a voltage can be applied by an external power source to the flip-chip light emitting diode 1.

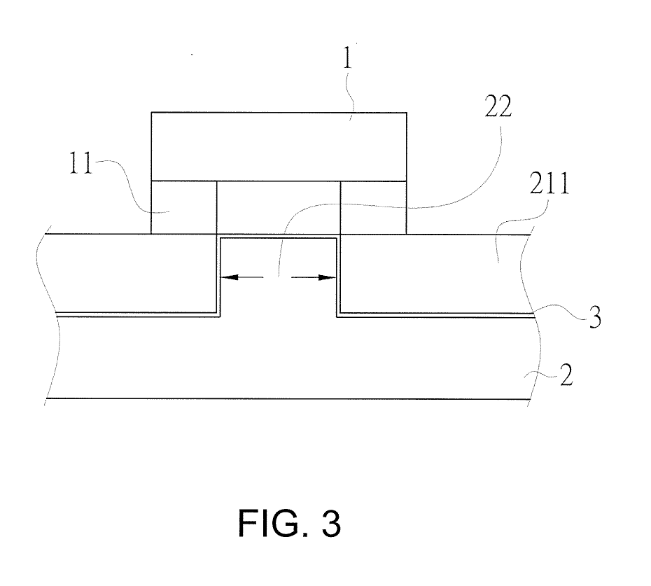

FIG. 3 is a cross-sectional schematic view of a device illustrating a circuit structure of a flip-chip light emitting diode according to the first preferred embodiment of the invention. Here, FIG. 3 is a cross-sectional view illustrating a flip-chip light emitting diode device along an AA′ line shown in FIG. 2. Referring to FIG. 3, an insulating layer 3 is formed on a surface of the substrate 2, and the reflective and conductive surfaces 211 (i.e. bonding pads) are disposed on the insulating layer 3. The insulating layer is formed of a material having a high reflectivity, such as one of a silicon compound and epoxy compound, for example. In addition, the substrate 2 is one of an aluminum substrate, a copper substrate, and other suitable metallic substrates. In a preferred embodiment of the invention, the circuit structure of the flip-chip light emitting diode includes the substrate 2, the insulating layer 3 is formed on the surface of the substrate 2, and the reflective and conductive surfaces 211 are disposed on the insulating layer 3. The insulating layer 3 is configured to electrically isolate the substrate 2 and the reflective and conductive surfaces 211 that are both formed of metallic materials from each other, so as to prevent a short circuit generated therebetween. As shown in FIG. 3, a plurality of holes are formed on the substrate 2 by performing a photolithography process and a wet or dry etching process, the insulating layer 3 is formed on the surface of the substrate 2 by performing a deposition process, and the reflective and conductive surfaces 211 is formed of a metallic material at the holes. In addition, the minimum gap 22 between two adjacent reflective and conductive surfaces 211 is in a range from 75 micrometers to 250 micrometers. The flip-chip light emitting diode 1 spans across the minimum gap 22 of the reflective and conductive surfaces 211, and is bonded to two different reflective and conductive surfaces 211 through eutectic bonding with at least two electrodes 11, so that the flip-chip light emitting diode 1 is bonded with the substrate 2 successfully.

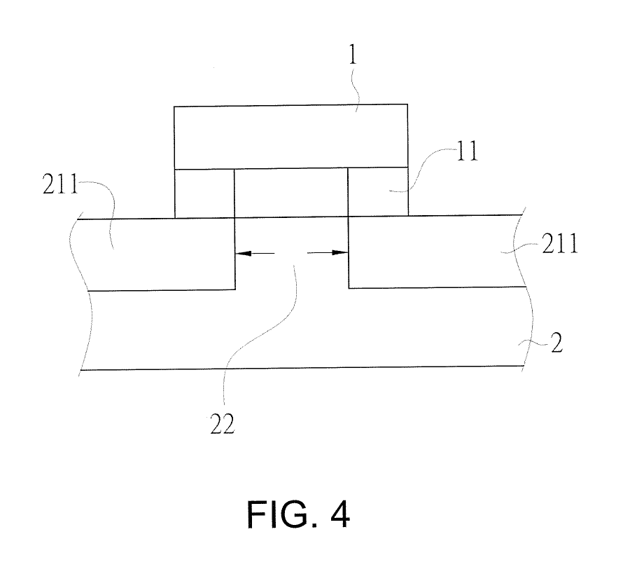

Moreover, referring to FIG. 4, FIG. 4 is a cross-sectional schematic view of a device illustrating a circuit structure of a flip-chip light emitting diode according to a second preferred embodiment of the invention, and is also structure cross-sectional view illustrating the flip-chip light emitting diode device along the AA′ line shown in FIG. 2. Here, the substrate 2 is formed of an insulating ceramic material. As shown in FIG. 4, a plurality of holes are formed on the substrate 2 by performing a photolithography process and a wet or dry etching process, and the reflective and conductive surfaces 211 are formed of a metallic material and are formed at the holes of the substrate 2 by performing a deposition process. In addition, the minimum gap 22 between two adjacent reflective and conductive surface 211 is in a range from 75 micrometers to 250 micrometers, and the flip-chip light emitting diode 1 spans across the minimum gap 22 of the reflective and conductive surfaces 211, and is bonded to two different reflective and conductive surfaces 211 through eutectic bonding with at least two electrodes 11, so that the flip-chip light emitting diode 1 is bonded with the substrate 2 successfully.

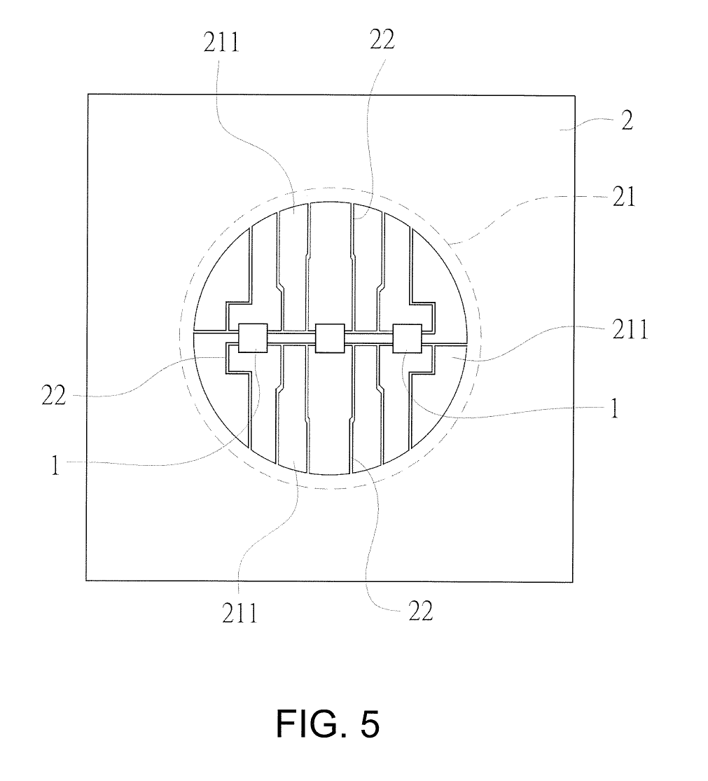

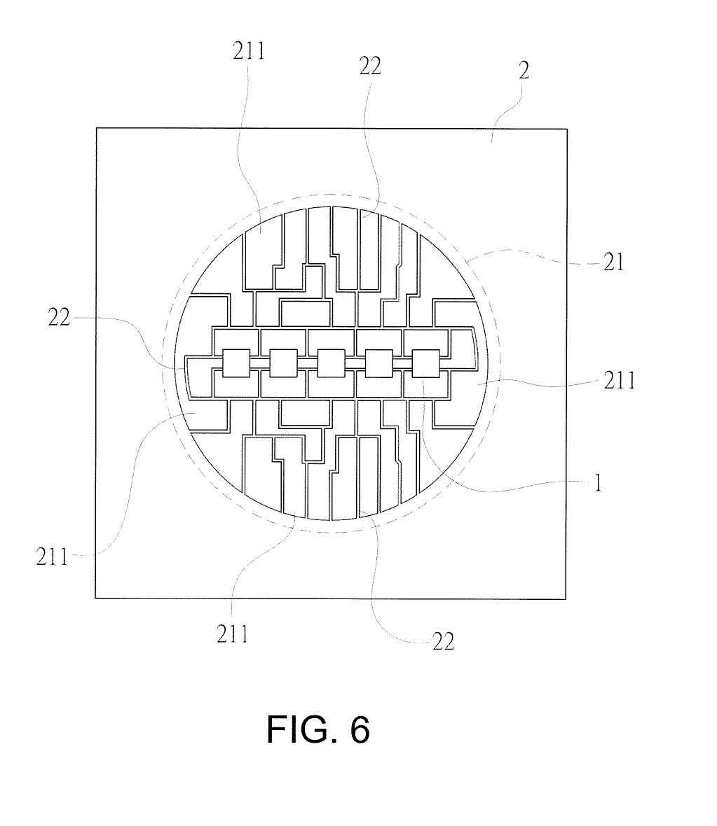

In the actual practice of the circuit structure of the flip-chip light emitting diode for increasing light reflection, first of all, the light emitting surface 21 is defined on the surface of the substrate 2, and then, referring to FIGS. 2 and 3, two holes are formed on the substrate 2 by performing a photolithography process and a wet or dry etching process. Then, two reflective and conductive surfaces 211 are formed at the holes of the substrate 2 by performing a deposition process. In addition, the reflective and conductive surfaces 211 are formed by depositing a metallic material, and the minimum gap 22 between two adjacent reflective and conductive surfaces 211 is in a range from 75 micrometers to 250 micrometers. Moreover, the flip-chip light emitting diode 1 spans across the minimum gap 22 of the reflective and conductive surfaces 211, and at least two electrodes 11 are respectively bonded to two different reflective and conductive surfaces 211 through eutectic bonding, so that the flip-chip light emitting diode 1 is bonded with the substrate 2 successfully. Referring to FIG. 5, FIG. 5 is a top view of a circuit structure illustrating a circuit structure of a flip-chip light emitting diode according to a third preferred embodiment of the invention. Here, 13 reflective and conductive surfaces 211 are formed on the light emitting surface 21 defined on the substrate 2. The minimum gap 22 between two adjacent reflective and conductive surface 211 is in a range from 75 micrometers to 250 micrometers. Also, at least two electrodes 11 of the flip-chip light emitting diode 1 are respectively bonded to two different reflective and conductive surfaces 211 through eutectic bonding, so that the flip-chip light emitting diode 1 is bonded with the substrate 2 successfully. However, it should be noted that a position where the flip-chip light emitting diode 1 is disposed in FIG. 5 is merely shown for an illustrative purpose, and the invention is not limited thereto. Also, people having ordinary skills in the art shall understand that the way that the flip-chip light emitting diode 1 is disposed may differ as the circuit structure and layout differ, and the position where the flip-chip light emitting diode 1 may also differ. However, such difference does not affect the actual practice of the invention. Furthermore, referring to FIG. 6, FIG. 6 is a top view of a circuit structure illustrating a circuit structure of a flip-chip light emitting diode according to a fourth preferred embodiment of the invention. Here, 35 reflective and conductive surfaces 211 are formed on the light emitting surface 21 defined on the substrate 2. In this embodiment, a light reflection area 111 is also formed of a metallic material. Also, at least two electrodes 11 of the flip-chip light emitting diode 1 are respectively bonded to two different reflective and conductive surfaces 211 through eutectic bonding, so that the flip-chip light emitting diode 1 is bonded with the substrate 2 successfully. However, it should be noted that a position where the flip-chip light emitting diode 1 is disposed in FIG. 6 is merely shown for an illustrative purpose, and the invention is not limited thereto. Also, people having ordinary skills in the art shall understand that the way that the flip-chip light emitting diode 1 is disposed may differ as the circuit structure and layout differ, and the position where the flip-chip light emitting diode 1 may also differ. However, such difference does not affect the actual practice of the invention. According to the following table, where calculation results of proportions of the areas of the reflective and conductive surfaces 211 are provided, the total areas of the reflective and conductive surfaces 211 of the flip-chip light emitting diode devices in Sample 1 to Sample 6 account for 85% to 99% of the area of the light emitting surface 21. Compared with other flip-chip light emitting diode devices whose total areas of reflective and conductive surfaces 211 account for less than 85% of the area of the light emitting surface 21, the flip-chip light emitting diode devices in Sample 1 to Sample 6 have a more preferable luminous efficiency, and is thus capable of effectively improving the luminous efficiency.

| | Sam- | Sam- | Sam- | Sam- | Sam- | Sam- |
|---|---|---|---|---|---|---|
| | ple 1 | ple 2 | ple 3 | ple 4 | ple 5 | ple 6 |
| Total area of reflective | 29.1 | 56.6 | 60.1 | 60.9 | 112.1 | 270.5 |
| and conductive surfaces | | | | | | |
| Area of light emitting | 34.2 | 62.2 | 62.2 | 62.2 | 124.7 | 301.7 |
| surface | | | | | | |
| Proportion of reflective | 85% | 91% | 98% | 98% | 90% | 90% |
| and conductive surfaces | | | | | | |

Based on the above description of embodiments, compared with the conventional technology, the circuit structure of the flip-chip light emitting diode according to the embodiments of the invention has the following advantage:

1. In the circuit structure of the flip-chip light emitting diode according to the embodiments of the invention, the proportion of the total area of the plurality of reflective and conductive surfaces on a circuit board of the flip-chip light emitting diode is increased to 80% to 99% of the area of the light emitting surface. Thus, light beams emitted by the flip-chip light emitting diode may be reflected by the metallic reflective and conductive surfaces, allowing the flip-chip light emitting diode device to emit a greater amount of light, so as to effectively improve the luminous efficiency of the flip-chip light emitting diode device.

In view of the foregoing, based on the embodiment described above, the efficacy of the circuit structure of the flip-chip light emitting diode according to the embodiments of the invention is certainly demonstrated, and such efficacy is not previously disclosed, thus meeting patentable conditions. The invention is thus filed in request for grant of a patent right pursuant to the relevant provisions.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit structure of a flip-chip light emitting diode, configured for assembling of at least one flip-chip light emitting diode, wherein each of the flip-chip light emitting diode has at least two electrodes, the circuit structure comprises a substrate having a light emitting surface located on a surface thereof, a plurality of reflective and conductive surfaces disposed on the light emitting surface, and the reflective and conductive surfaces are configured for assembling of the electrodes of the flip-chip light emitting diode, such that the at least one flip-chip light emitting diode is connected in series, in parallel, or in series-parallel on the light emitting surface, wherein a total area of the reflective and conductive surfaces accounts for 80% to 99% of an area of the light emitting surface.

2. The circuit structure of the flip-chip light emitting diode as claimed in claim 1, wherein a minimum gap between two adjacent reflective and conductive surfaces is in a range from 75 micrometers to 250 micrometers.

3. The circuit structure of the flip-chip light emitting diode as claimed in claim 2, wherein the reflective and conductive surfaces are formed of a metallic material.

4. The circuit structure of the flip-chip light emitting diode as claimed in claim 1, further comprising an insulating layer formed on the surface of the substrate, wherein the reflective and conductive surfaces are located on the insulating layer.

5. The circuit structure of the flip-chip light emitting diode as claimed in claim 4, wherein the insulating layer is formed of a material having a high reflectivity.

6. The circuit structure of the flip-chip light emitting diode as claimed in claim 5, wherein a material of the insulating layer is one of a silicon compound and an epoxy compound.

7. The circuit structure of the flip-chip light emitting diode as claimed in claim 4, the substrate is one of an aluminum substrate and a copper substrate.

8. The circuit structure of the flip-chip light emitting diode as claimed in claim 1, wherein the substrate is formed of a ceramic material.
